(19) United States
(12) Patent Application Publication
(10) Pub. No.: US 2025/0300192 A1
(43) Pub. Date: Sep. 25, 2025

(54) SEPARATOR AND METHOD FOR MANUFACTURING THE SEPARATOR

(71) Applicants: TOYOTA JIDOSHA KABUSHIKI KAISHA, Toyota-shi Aichi-ken (JP); NIPPON KINZOKU CO., LTD., Minato-ku Tokyo (JP)

(72) Inventors: Yuzo ISHIKAWA, Toyota-shi Aichi-ken (JP); Osamu YAMAZAKI, Saitama-shi Saitama-ken (JP); Ippei KIKUCHI, Katsushika-ku Tokyo (JP); Sayuri FUJIMOTO, Nerima-ku Tokyo (JP)

(73) Assignees: TOYOTA JIDOSHA KABUSHIKI KAISHA, Toyota-shi Aichi-ken (JP); NIPPON KINZOKU CO., LTD., Minato-ku Tokyo (JP)

(21) Appl. No.: 19/085,615

(22) Filed: Mar. 20, 2025

(30) Foreign Application Priority Data
Mar. 25, 2024 (JP) 2024-047772

(51) Int. Cl. H01M 8/0228; C23C 14/02; C23C 14/06; H01M 8/021; H01M 8/0267

(52) U.S. Cl. CPC H01M 8/0228; H01M 8/021; H01M 8/0267; C23C 14/021; C23C 14/0605

(57) ABSTRACT

A separator formed of stainless steel for a fuel cell includes a coolant contact surface that is configured to come into contact with a coolant and a gas contact surface that is configured to come into contact with gas. The coolant contact surface has a conductive passive film. The gas contact surface has a corrosion-resistant metal intermediate layer on a base material, and a conductive layer on the corrosion-resistant metal intermediate layer.

### CROSS-REFERENCE TO RELATED APPLICATION

This application claims priority to Japanese Patent Application No. 2024-047772 filed on Mar. 25, 2024, incorporated herein by reference in its entirety.

### BACKGROUND

### 1. Technical Field

The present disclosure relates to a separator and a method for manufacturing the separator, specifically to a separator for a fuel cell and a method for manufacturing the separator for a fuel cell.

### 2. Description of Related Art

A fuel cell has a stack structure in which a predetermined number of unit cells that generate electromotive force by the reaction of a fuel gas (hydrogen) and an oxidant gas (oxygen) are stacked. Each unit cell includes a film electrode assembly having an anode electrode layer and a cathode electrode layer (a catalyst layer and a gas diffusion layer) on both surfaces of an electrolyte film, and separators arranged on both surfaces of the film electrode assembly.

The separator for the fuel cell has a function of electrically connecting the unit cells in series and also has a function as a partition wall for cutting off the fuel gas, the oxidant gas, and coolant from one another.

Various studies have been conducted on such separators for fuel cells.

For example, Japanese Unexamined Patent Application Publication No. 2010-86897 (JP 2010-86897 A) discloses a separator for a fuel cell characterized by including a base layer formed of a separator base material, a metal layer that is formed on the base layer and provided to be continuous with the surface of the base layer, and a metal nitride layer formed on the metal layer.

Japanese Unexamined Patent Application Publication No. 2010-140886 (JP 2010-140886 A) discloses a stainless steel material for a separator of a solid polymer electrolyte fuel cell, the stainless steel material being characterized by including a stainless steel base material, an oxide film provided on the surface of the stainless steel base material, a conductive layer that is provided on the surface of the oxide film and includes a non- metallic conductive material, and a conductive material that is provided so as to penetrate through the oxide film and is electrically connected to the stainless steel base material and the conductive layer, and characterized in that the non-metallic conductive material provided on the surface of the oxide film includes graphite carbon, and when comparing the peak intensities of diffraction lines from atomic planes obtained by performing wide-angle X-ray diffraction measurement of crystals of the graphite carbon, the ratio of the peak intensity of the diffraction line from the (110) atomic plane to the peak intensity of the diffraction line from the (004) atomic plane is less than 0.1.

Japanese Unexamined Patent Application Publication No. 2022-45138 (JP 2022-45138 A) discloses a separator for a fuel cell that includes a metal base material, a corrosion-resistant metal intermediate layer formed on the metal base material, and a carbon layer formed on the corrosion-resistant metal intermediate layer, the intensity ratio (I_{D}/I_{G}) of the D band peak intensity (ID) to the G band peak intensity (IG) in a Raman spectrum of the carbon layer being equal to or more than 0.70 and less than 0.95.

### SUMMARY

Since a separator for a fuel cell (hereinafter simply referred to as “separator”) also plays a role in passing generated current therethrough to an adjacent cell, the base material constituting the separator is required to have high electrical conductivity and corrosion resistance sufficient to maintain the high electrical conductivity for a long period of time even in a high-temperature and acidic atmosphere inside the fuel cell. Here, the high electrical conductivity means low contact resistance. The contact resistance means a voltage drop caused by an interfacial phenomenon between the electrode and the separator surface.

For this reason, pure titanium or titanium alloys which are desirable in electrical conductivity and corrosion resistance are often used as the base materials for separators, which is one of major factors increasing the cost of producing the separators.

Therefore, in order to reduce the cost, attempts have been made to produce separators having electrical conductivity and corrosion-resistant by using an inexpensive base material such as stainless steel as the base material and forming a layer that imparts electrical conductivity and corrosion resistance on the surface of the base material.

The layer that imparts electrical conductivity and corrosion resistance to the stainless steel is deposited (formed), for example, by a physical vapor deposition (PVD) treatment.

However, such a PVD treatment requires processing in a vacuum and a plurality of steps as a film forming process. Furthermore, in a related art, such a PVD treatment is performed on both a surface (coolant contact surface) of the separator that will come into contact with a coolant (e.g., cooling water) and a surface (gas contact surface) of the separator that will come into contact with a supply gas (fuel gas and/or oxidant gas), so that there is a possibility that the separator has excessive performance at some locations.

Therefore, the present disclosure provides a fuel cell separator having sufficient corrosion resistance and low contact resistance and a method for manufacturing the separator at low cost.

The present disclosing party has considered various techniques for solving the above-mentioned problems, and consequently has found that two base materials formed of stainless steel each having a film obtained by imparting electrical conductivity (conductive passive film) formed on a surface thereof are stacked together such that coolant contact surfaces face each other inward, and then a physical vapor deposition treatment is performed on exposed gas contact surfaces to form corrosion-resistant metal intermediate layers as intermediate layers on the base materials, and conductive layers as upper layers are formed on the corrosion-resistant metal intermediate layers, whereby it is possible to simultaneously manufacture two fuel cell separators each having sufficient corrosion resistance and low contact resistance, that is, high electrical conductivity according to each contact surface, and has completed the present disclosure.

A separator formed of stainless steel for a fuel cell according to a first aspect of the present disclosure, includes a coolant contact surface that is configured to come into contact with a coolant, and a gas contact surface that is configured to come into contact with gas. The coolant contact surface has a conductive passive film. The gas contact surface has a corrosion-resistant metal intermediate layer on a base material and a conductive layer on the corrosion-resistant metal intermediate layer.

In the separator according to the first aspect of the present disclosure, the Cr/Fe ratio related to atomic % in the conductive passive film analyzed by surface X-ray photoelectron spectroscopy may be equal to 2 or more. The concentration of F in the conductive passive film analyzed by surface X-ray photoelectron spectroscopy may be equal to 0.1 atomic % or more. The concentration of Li in the conductive passive film analyzed by glow discharge optical emission spectroscopy may be equal to 0.05 atomic % or more.

A method for manufacturing a separator for a fuel cell according to a second aspect of the present disclosure includes (i) applying a conductive passive film to a base material of stainless steel to prepare a conductive base material, (ii) stacking two or more conductive base materials obtained in the applying such that a gas contact surface of each of the two or more conductive base materials is entirely exposed, and (iii) performing a PVD treatment on the gas contact surfaces of the two or more conductive base materials stacked in the stacking to form corrosion-resistant metal intermediate layers on the base materials and conductive layers on the corrosion-resistant metal intermediate layers. The gas contact surface is to come into contact with gas entirely. The gas contact surfaces of the two or more conductive base materials are exposed.

In the method for manufacturing a separator for a fuel cell according to the second aspect of the present disclosure, the applying includes (A) implanting fluorine into a passive film, (B) implanting lithium into the passive film, and (C) eluting iron in the passive film.

The present disclosure provides a separator for a fuel cell that has sufficient corrosion resistance and low contact resistance, and a method for manufacturing the separator at low cost.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic sectional view showing a comparison between a cell including an embodiment of a fuel cell separator according to the present disclosure and a cell including a fuel cell separator according to a related art;

FIG. 2A is a schematic diagram of an embodiment of a method for manufacturing a fuel cell separator according to the present disclosure;

FIG. 2B is a schematic diagram of a method for manufacturing a fuel cell separator according to the related art;

FIG. 3A is a schematic diagram which specifically shows a surface treatment step in the manufacturing method of the related art;

FIG. 3B is a schematic diagram which shows the embodiment of the method for manufacturing a fuel cell separator according to the present disclosure in more detail;

FIG. 3C is a diagram showing a comparison between the method of the present disclosure and the method of the related art;

FIG. 4 is a graph showing results of contact resistance for Comparative Example 1, Reference Example 1, and Example 1;

FIG. 5 is a graph showing a result of XPS analysis for a coolant contact surface of Example 1;

FIG. 6A is a graph showing a result of the TOF-SIMS depth analysis for the coolant contact surface of Example 1;

FIG. 6B is a graph showing a result of the TOF-SIMS depth analysis for the coolant contact surface of Example 1;

FIG. 6C is a graph showing a result of the TOF-SIMS depth analysis for the coolant contact surface of Example 1;

FIG. 6D is a graph showing a result of the TOF-SIMS depth analysis for the coolant contact surface of Example 1;

FIG. 7 is a graph showing results of GD-OES depth analysis for the coolant contact surfaces of Example 1 and Comparative Example 1; and

FIG. 8 is a graph showing a result of TEM-EDX element mapping analysis for the coolant contact surface of Example 1.

### DETAILED DESCRIPTION OF EMBODIMENTS

Embodiments of the present disclosure will be described in detail below.

In the present specification, the features of the present disclosure will be described with reference to the drawings as appropriate. In the drawings, the dimensions and shapes of respective portions are exaggerated for clarity, and the actual dimensions and shapes are not accurately depicted. Therefore, the technical scope of the present disclosure is not limited to the dimensions and shapes of the respective portions shown in these drawings. Note that a separator of the present disclosure and a method for manufacturing the same are not limited to the embodiments described below, and can be implemented in various forms with modifications, improvements, etc. that a person skilled in the art can make as long as they do not deviate from the gist of the present disclosure.

The present disclosure relates to a fuel cell separator formed of a stainless steel having a coolant contact surface which comes into contact with a coolant and a gas contact surface which comes into contact with gas, the coolant contact surface and the gas contact surface having a specific film or layer.

In the present disclosure, the base material of the separator is not limited as long as it is stainless steel. Examples of stainless steel include austenitic stainless steel, ferritic stainless steel, martensite stainless steel, austenitic-ferritic (two-phase) stainless steel, and precipitation-hardening type stainless steel, and specific examples thereof include SUS301, SUS304, SUS304L, SUS316, SUS316L, SUS430, SUS430J1L, SUS434, SUS444, SUS447, and SUS631. Examples of surface finish include bright annealing finish (BA), pickling finish (2D), light rolling finish after pickling (2B), and temper rolling finish.

It is possible to reduce the raw material cost by selecting stainless steel as the base material for the separator.

The thickness of the base material is not limited, but it is usually in a range from 0.05 mm to 0.2 mm, and in one embodiment, in a range from 0.08 mm to 0.12 mm.

It is possible to reduce the raw material cost by setting the thickness of the base material to the ranges.

The coolant contact surface of the separator of the present disclosure that comes into contact with the coolant has a conductive passive film. Note that the term “coolant contact surface” means a surface of the separator that comes into contact with the coolant, and with respect to the base material, it means a surface of the base material that comes into contact with the coolant when a separator is produced as a product.

Here, the conductive passive film means a film obtained by implantation fluorine and lithium into a passive film that is normally formed on the surface of stainless steel as a base material and further imparting electrical conductivity and corrosion resistance to the passive film by increasing the Cr ratio.

The Cr/Fe ratio related to atomic % in the conductive passive film analyzed by surface X-ray photoelectron spectroscopy (XPS) is usually equal to 2 or more, and in one embodiment, it is equal to 2.5 or more. Since the film properties can be improved by increasing the Cr ratio and decreasing the Fe ratio on the surface of the conductive passive film as described above, there is no upper limit value to the Cr/Fe ratio.

The F concentration in the conductive passive film analyzed by surface X-ray photoelectron spectroscopy (XPS) is usually equal to 0.1 atomic % or more, and in one embodiment, it is equal to 1.0 atomic % or more. There is no upper limit value to the F concentration. The F concentration is usually equal to 20 atomic % or less. Note that the concentrations of various elements in the conductive passive film by XPS (Cr/Fe ratio (atomic %), F concentration, etc.) can be measured by using the following measurement conditions: X-ray photoelectron spectroscopy device: PHI5000VersaProbeII (manufactured by ULVAC-PHI company), X-ray source: Al-Kα (1486.6 eV), X-ray source conditions: 15 kV (25 W), shift correction: C—C, C—H bonding energy of C1s is 284.8 eV, beam diameter: 100 μmΦ, measurement range: about 200 μm×1000 μm.

The Li concentration in the conductive passive film analyzed by glow discharge optical emission spectrometry (GD-OES) is usually equal to 0.05 atomic % or more, and in one embodiment, it is equal to 0.1 atomic % or more. There is no upper limit value for the Li concentration. The Li concentration is usually equal to 5 atomic % or less. Note that the Li concentration in the conductive passive film by GD-OES can be measured using the following measurement condition: glow discharge optical emission spectrometry device: GD-Profiler2 (manufactured by HORIBA, Ltd.), discharge gas: Ar gas, gas pressure: 600 Pa, electrode: 4 mm electrode.

When Li, F acting as electron carriers have been implanted into the passive film, the electrical conductivity of the passive film is improved, and the contact electrical resistance of the passive film being formed can be significantly improved. Furthermore, by modifying the passive film to a composition mainly including Cr oxide and Cr hydroxide, the corrosion resistance is improved, and the film does not change even when it is left in the atmosphere for a long time, so that it is possible to prevent or restrain deterioration of the surface contact electrical resistance over time.

The thickness of the conductive passive film is not limited. The average thickness of the conductive passive film is usually in a range from 1 nm to 10 nm, and in one embodiment, in a range from 2 nm to 6 nm. The average thickness of the conductive passive film can be measured, for example, by cross-sectional TEM observation.

When the thickness of the conductive passive film is set in the ranges described above, sufficient electrical conductivity and corrosion resistance can be ensured as a coolant contact surface.

The gas contact surface of the separator of the present disclosure that comes into contact with gas (fuel gas and/or oxidant gas) has a corrosion-resistant metal intermediate layer on the base material and a conductive layer on the corrosion-resistant metal intermediate layer. With respect to the separator, the “gas contact surface” means a surface that comes into contact with gas in the separator, and with respect to the base material, it means a surface that comes into contact with gas when the separator has been produced as a product.

The corrosion-resistant metal intermediate layer is a layer for imparting corrosion resistance to the separator, and it is not limited thereto. An example of the corrosion-resistant metal intermediate layer includes a titanium layer.

The separator of the present disclosure has a corrosion-resistant metal intermediate layer, which makes it possible to ensure the corrosion resistance of the separator.

The conductive layer is a layer for imparting electrical conductivity to the separator, and it is not limited thereto. An example of the conductive layer includes a carbon layer.

The separator of the present disclosure has a conductive layer, which makes it possible to ensure the low contact resistance for the separator.

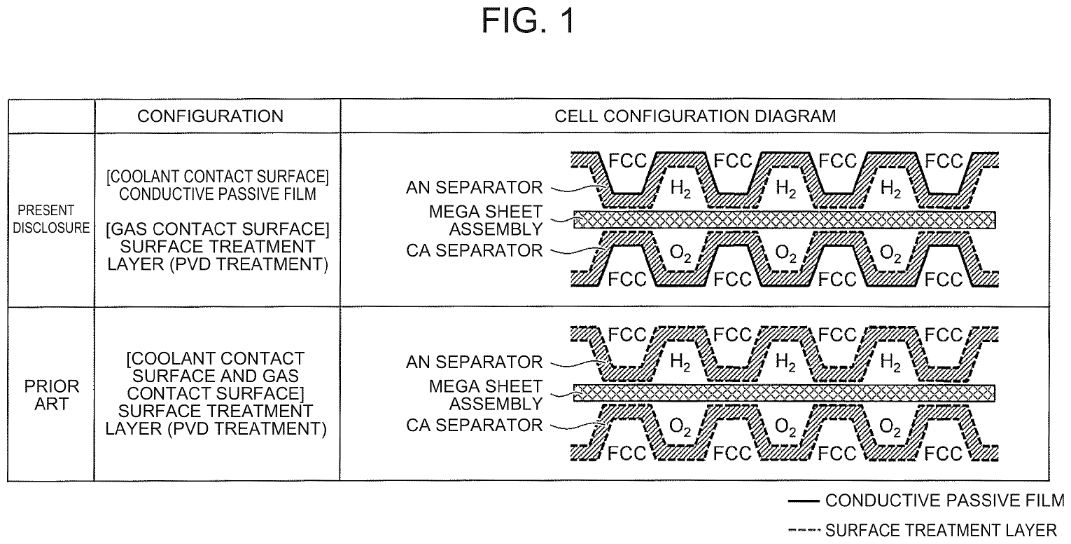

FIG. 1 is a schematic sectional view showing a comparison between one embodiment of a fuel cell separator according to the present disclosure and a fuel cell separator according to a related art. In FIG. 1, “FCC” is an abbreviation for Fuel Cellstuck Coolant which indicates a fuel cell coolant, “AN separator” indicates an anode separator, “CA separator” indicates a cathode separator, and “MEGA sheet assembly” indicates a film electrode gas diffusion layer conjugate sheet assembly. The AN separator and the CA separator are made of the same material which constitutes a separator including a surface treatment layer. On the other hand, the AN separator and the CA separator have different flow channel shapes suitable for the respective characteristics as fuel cells. Since the flow channel shape is different from the essence of the present disclosure, the AN separator and the CA separator are depicted as having the same structure for the sake of simplicity in the drawings including FIG. 1.

As shown in FIG. 1, in a fuel cell separator of the present disclosure, a conductive passive film is formed on a coolant contact surface that comes into contact with the coolant, and a surface treatment layer is formed on a gas contact surface that comes into contact with gas. In a fuel cell separator of a related art, surface treatment layers are formed on both a coolant contact surface and a gas contact surface. Since the surface treatment layer usually includes a corrosion-resistant metal intermediate layer and a conductive layer, the fuel cell separator of the related art in which the surface treatment layers are formed on both the surfaces thereof is expensive and has excessive performance for the coolant contact surface.

The present disclosure further relates to a method for manufacturing a fuel cell separator of the present disclosure.

The method for manufacturing a fuel cell separator of the present disclosure includes (i) a conductive passive film forming step of preparing a conductive base material, (ii) a step of stacking two or more conductive base materials, and (iii) a surface treatment step of forming a corrosion-resistant metal intermediate layer and a conductive layer on exposed gas contact surfaces of the two or more conductive base materials. Here, the conductive base material indicates stainless steel having a conductive passive film.

The step of (i) includes (A) a step of implanting fluorine into the passive film, (B) a step of implanting lithium into the passive film, and (C) a step of eluting iron in the passive film.

In the step of (i), the base material to be used is as described above.

The thickness of the base material is not limited, but it is usually in a range from 0.05 mm to 0.2 mm, and in one embodiment, in a range from 0.08 mm to 0.12 mm.

The thickness of the base material is set in the above ranges, whereby it is possible to reduce the raw material cost.

A base material that has been pressed into the final shape of the separator in advance may be used as the base material.

By using a pre-pressed base material as the base material, it is possible to achieve a separator without further pressing after a titanium layer and a conductive metal oxide layer are formed.

In the step of (A), examples of a method for implanting fluorine into the passive film include a method for performing a dip treatment (chemical treatment) on stainless steel in an aqueous solution containing fluoride ions or a method for performing an electrolytic treatment (electrochemical treatment) on stainless steel.

The fluoride ion source to be used for implantation of fluorine is not limited, and any compound may be used as long as it is hydrofluoric acid or a fluorine compound that dissolves in water to generate fluoride ions. Examples of the fluoride ion source include alkali metal fluorides (for example, sodium fluoride, potassium fluoride, and the like), ammonium fluoride, antimony trifluoride, copper fluoride, sodium hydrogen difluoride, potassium hydrogen difluoride, etc. In one embodiment, the fluoride ion source is an alkali metal fluoride such as sodium fluoride or potassium fluoride.

In order to electrochemically implant fluoride, stainless steel is subjected to direct current or pulse electrolysis (polarity is anode and cathode) in an aqueous solution of hydrogen fluoride or an acidic aqueous solution in which nitric acid, sulfuric acid, phosphoric acid, or the like is added to the fluoride ion source. The pH of the treatment solution is usually in a range from 0 to 3, and in one embodiment, in a range from 0 to 2. The fluoride concentration can be set in a wide range, usually from 0.001 kmol/m³ to a saturated concentration. The aqueous solution does not need to be warmed, and can be used usually, for example, in a range from 10° C. to 30° C., and in one embodiment, at room temperature (e.g., 20° C.). The direct current or pulse electrolysis condition is in a range from 0.001 A/dm² to 50 A/dm² (for both the anode and the cathode), and in one embodiment, it is in a range from 0.1 A/dm² to 10 A/dm². The electrolysis time is usually in a range from 5 seconds to 600 seconds, and in one embodiment, it is in a range from 10 seconds to 180 seconds.

In order to chemically implant fluorine, the dip treatment is performed in a solution of hydrofluoric acid or a solution of the above-mentioned fluoride ion source to which oxidant is added. The fluoride concentration can be set usually in a wide range from 0.001 kmol/m⁻³ to a saturated concentration.

Examples of the oxidant include nitric acid, potassium permanganate, and hydrogen peroxide. The concentration of the oxidant is usually in a range from 0.1 kmol/m³ to 10 kmol/m³, and in one embodiment, it is in a range from 1 kmol/m³ to 5 kmol/m³. The temperature of the aqueous solution is usually in a range from 20° C. to 80° C., and in one embodiment, it is in a range from 30° C. to 60° C. The dip time is usually in a range from 10 seconds to 10 minutes, and in one embodiment, it is in a range from 1 minute to 10 minutes.

In the step of (B), examples of the method for implanting lithium into the passive film include a method for performing a dip treatment (chemical treatment) on stainless steel in an aqueous or non-aqueous solution containing lithium ions or subjecting stainless steel to an electrolytic treatment (electrochemical treatment).

The lithium ion source for implantation of lithium is not limited, and any compound can be used as long as it is a lithium compound that dissolves in water or a non-aqueous solvent to generate lithium ions. For example, oxygen compounds include lithium hydroxide, lithium oxide, etc., halides include lithium chloride, lithium bromide, lithium iodide, etc., and oxygen acid salts include lithium nitrate, lithium sulfate, etc. Non-aqueous solvents include ethanol, methanol, dimethyl ether, diethyl ether, methyl ethyl ether, etc. A mixture of water and a water-miscible non-aqueous solvent may also be used.

The concentration of the lithium compound in the aqueous or non-aqueous solution containing the lithium ion source can be set in a wide range, usually from 0.1 kmol/m³ to a saturated solution. The solution does not need to be warmed, and it is usually in a range from 10° C. to 30° C., and in one embodiment, it is at room temperature (for example, 20° C.). In the case of the dip treatment, the treatment time is usually in a range from 10 seconds to 10 minutes, and in one embodiment, it is in a range from 30 seconds to 5 minutes. In the case of direct current or pulse electrolysis (polarities are anode and cathode), the direct current or pulse electrolysis density is in a range from 0.001 A/dm² to 10 A/dm² (for both the anode and the cathode), and in one embodiment, it is in a range from 0.1 A/dm² to 5 A/dm². The electrolysis time is usually in a range from 10 seconds to 10 minutes, and in one embodiment, it is in a range from 20 seconds to 5 minutes.

An effective method for implanting fluoride ions and lithium ions into the passive film is to repeatedly carry out the steps of (A) and (B). The order of the steps of (A) and (B) is not limited. In one embodiment, the step of (A) is first carried out, and then the step of (B) is carried out.

In the step of (C), a method for preferentially eluting iron in the passive film includes a method for performing a dip treatment in an aqueous solution containing fluoride ions. Note that it is effective to perform a heat treatment in the atmosphere or in an inert gas atmosphere such as nitrogen gas or Ar gas before this treatment. This is considered to be because Fe concentrated in the outermost layer of the passive film by the heat treatment easily forms a complex with fluoride ions by the subsequent dip treatment in an aqueous solution containing fluoride ions, and is eluted from the passive film. By preferentially eluting Fe in the passive film, the film is modified to have a composition mainly including Cr oxide and Cr hydroxide.

In order to elute iron in the passive film, the stainless steel may be subjected to the dip treatment in an aqueous solution containing fluoride ions. The aqueous solution may be hydrofluoric acid or an aqueous acid solution obtained by adding an acid to the fluoride ion source. The pH is usually in a range from 0 to 3, and in one embodiment, it is in a range from 0 to 2. The fluoride concentration may be set in a wide range, usually from 0.001 kmol/m³ to a saturated concentration. Examples of acids for adjusting the pH include nitric acid, sulfuric acid, and phosphoric acid. The concentration is usually in a range from 0.01 kmol/m³ to 10 kmol/m³, and in one embodiment, in a range from 0.1 kmol/m³ to 5 kmol/m³. The temperature of the aqueous solution is usually in a range from 10° C. to 80° C., and in one embodiment, it is in a range from 20° C. to 60° C. The dip time is usually in a range from 5 seconds to 20 minutes, and in one embodiment, in a range from 5 seconds to 10 minutes.

Furthermore, in order to efficiently elute iron in the passive film, it is desirable to carry out a heat treatment in the atmosphere or in an inert gas atmosphere such as nitrogen or Ar before the dip treatment in the aqueous solution containing fluoride ions in the step of (C). The heat treatment temperature is usually in a range from 100° C. to 600° C., and in one embodiment, it is in a range from 140° C. to 500° C., and the treatment time is usually in a range from 1 second to 30 minutes, and in one embodiment, in a range from 10 seconds to 20 minutes.

This heat treatment forms an iron-concentrated layer on the outermost surface layer of the passive film, and the subsequent dip treatment in an aqueous solution containing fluoride ions causes Fe and the fluoride ions to easily form a complex thereof, which elutes into the solution. This treatment brings the passive film with a composition mainly including Cr, which is considered to improve corrosion resistance, so that deterioration of the film is prevented even when the film is left in the atmosphere for a long time, and deterioration of the surface contact electrical resistance over time is restrained.

As described above, by implanting Li and F serving as electron carriers into the passive film, it is possible to enhance the electrical conductivity of the passive film and significantly improve the contact electrical resistance of the passive film being formed. Furthermore, the passive film is modified to have a composition mainly including Cr oxides and hydroxides, whereby the corrosion resistance is enhanced, the film does not deteriorate even when left in the atmosphere for a long time, and deterioration of the surface contact electrical resistance over time can be prevented or restrained.

For example, see Japanese Unexamined Patent Application Publication No. 2008-277146 (JP 2008-277146 A) for a method of forming a conductive passive film on the surface of stainless steel.

The step of (i) may be performed on both surfaces of the base material, or on only the coolant contact surface of the base material.

In the step of (ii), two or more conductive base materials obtained in the step of (i) are stacked together such that one of the two surfaces of each conductive base material, i.e., the gas contact surface is exposed whereas the coolant contact surface is not exposed.

A method for stacking two or more conductive base materials is not limited as long as the two or more conductive base materials are stacked such that the entire gas contact surfaces thereof can be subjected to a surface treatment in the step of (iii) described in detail below. The method for stacking two or more conductive base materials can stack, for example, two conductive base materials together such that the coolant contact surfaces thereof face each other inward with the conductive base materials being fixed with a frame (jig) as necessary, and the entire gas contact surfaces thereof are exposed. The method for stacking two or more conductive base materials can stack two or more conductive base materials together by sticking the two or more conductive base materials onto, for example, both surfaces of a plate-like or film-like material with the material being interposed between the two or more conductive base materials such that the gas contact surfaces are exposed. Since the coolant contact surfaces are not exposed, no surface treatment is performed in the step of (iii), but if necessary, the entire or part of the coolant contact surface may be masked such that the conductive passive film is not damaged.

In the step of (ii), two or more conductive base materials are stacked together, which makes it possible to simultaneously perform the surface treatment on only the entire gas contact surfaces of two or more conductive base materials which are particularly required to have corrosion resistance and electrical conductivity in the step of (iii).

In surface treatment step of (iii), a surface treatment, i.e., a PVD treatment is performed on the gas contact surfaces of the two or more conductive base materials exposed in the step of (ii) to form corrosion-resistant metal intermediate layers on the base materials and conductive layers on the corrosion-resistant metal intermediate layers.

A method for forming the corrosion-resistant metal intermediate layer on the base material and the conductive layer on the corrosion-resistant metal intermediate layer is not limited because a method in the present technical field can be used.

For example, when the corrosion-resistant metal intermediate layer is formed on the base material, first, an etching step is performed to peel off the passive film on the base material, and then a metal layer as an intermediate layer is formed by a PVD method as an intermediate layer forming step. The corrosion-resistant metal intermediate layer is not limited as long as it can impart corrosion resistance to the separator. Examples of the corrosion-resistant metal intermediate layer include a titanium layer.

The PVD method for forming the metal layer is not limited, but examples thereof include a vacuum deposition method, a sputtering method, an ion plating method, etc.

For example, the titanium layer can be formed by using the sputtering method. Use of the sputtering method makes it possible to facilitate mass production management.

With respect to the sputtering method, conditions known in the present technical field (for example, see WO 2015/068776) can be used, for example, for a bias voltage to the base material, an initial vacuum in an apparatus chamber, a cleaning condition for the surface of a metal base material (for example, a condition for an argon bombardment treatment), a condition for a plasma generating gas, a film formation time, a film formation temperature, etc.

The thickness of the corrosion-resistant metal intermediate layer is not limited, but the average thickness thereof is usually in a range from 50 nm to 1000 nm, and in one embodiment, in a range from 50 nm to 300 nm. The average thickness of the corrosion-resistant metal intermediate layer can be measured, for example, by cross-sectional TEM observation.

By setting the upper limit of the thickness of the corrosion-resistant metal intermediate layer as described above, it is possible to obtain an effect of reducing the amount of corrosion-resistant metal to be used, and also to prevent excessive increase in film stress caused by the formation of the corrosion-resistant metal intermediate layer, whereby it is possible to restrain occurrence of cracks in the corrosion-resistant metal intermediate layer, deformation of the base material on which the corrosion-resistant metal intermediate layer is stacked, and the like. By setting the lower limit of the thickness of the corrosion-resistant metal intermediate layer as described above, it is possible to ensure sufficient corrosion resistance.

Next, a conductive layer is formed on the corrosion-resistant metal intermediate layer by the PVD method in a conductive layer forming step.

The conductive layer is not limited as long as it has electrical conductivity and can reduce the contact resistance of the separator. Examples of the conductive layer include a carbon layer, etc.

The PVD method for forming the conductive layer is not limited, but examples thereof include a vacuum deposition method, a sputtering method, an ion plating method, etc.

For example, the carbon layer can be formed by the sputtering method. The details of the condition for the sputtering method is the same as the condition for forming the corrosion-resistant metal intermediate layer.

For example, the carbon layer can be formed by using the ion plating method.

Examples of the ion plating method include, for example, an arc ion plating (AIP) method.

With respect to the arc ion plating method, conditions known in the present technical field (for example, see Japanese Unexamined Patent Application Publication No. 2008-204876) (JP 2008-204876 A) can be used, for example, for a bias voltage, an initial vacuum in an apparatus chamber, a cleaning condition for the surface of a metal base material (for example, a condition for an argon bombardment treatment), a condition for a plasma generating gas, a film formation time, a film formation temperature, etc.

The thickness of the conductive layer is not limited, but the average thickness thereof is usually in a range from 5 nm to 500 nm, and in one embodiment, in a range from 30 nm to 150 nm. The average thickness of the conductive layer can be measured, for example, by cross-sectional TEM observation.

By setting the thickness of the conductive layer within the above range, it is possible to ensure low contact resistance, that is, high conductivity for the separator.

The manufacturing method disclosed herein makes it possible to simultaneously manufacture two or more separators each having corrosion resistance and electrical conductivity which are required for the coolant contact surface, and sufficient corrosion resistance caused by the corrosion-resistant metal intermediate layer and the low contact resistance caused by the conductive layer which are required for the gas contact surface, so that it is possible to significantly reduce the manufacturing cost and improve manufacturing efficiency.

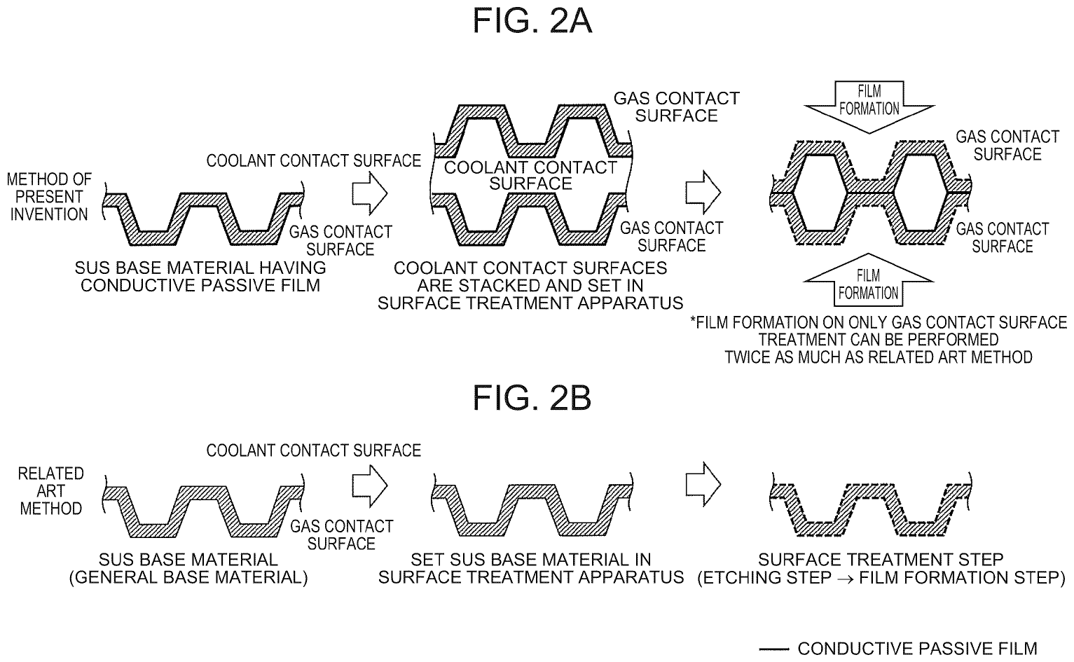

The embodiment of the method for manufacturing the fuel cell separator according to the present disclosure and a method for manufacturing a fuel cell separator according to a related art will be compared with each other with reference to FIGS. 2A and 2B. The following can be seen from FIG. 2A and FIG. 2B. In FIG. 2A showing the manufacturing method according to the present disclosure, stainless steel (SUS base material) having a conductive passive film on the surface thereof is used. The corrosion resistance and the electrical conductivity of the coolant contact surface can be sufficiently ensured by the conductive passive film. In other words, no further surface treatment is required to be performed on the coolant contact surface. Therefore, a surface treatment layer having more desirable corrosion resistance and electrical conductivity may be formed only on the gas contact surface. As described above, in the surface treatment step according to the present disclosure, two SUS base materials each having a conductive passive film are stacked together such that the coolant contact surfaces thereof faces each other and the gas contact surfaces thereof are exposed, so that the gas contact surfaces of two separators can be simultaneously subjected to the surface treatment. On the other hand, in FIG. 2B showing the manufacturing method of the related art, the surface treatment is performed on both the surfaces of a SUS base material, so that only one separator can be manufactured by one surface treatment.

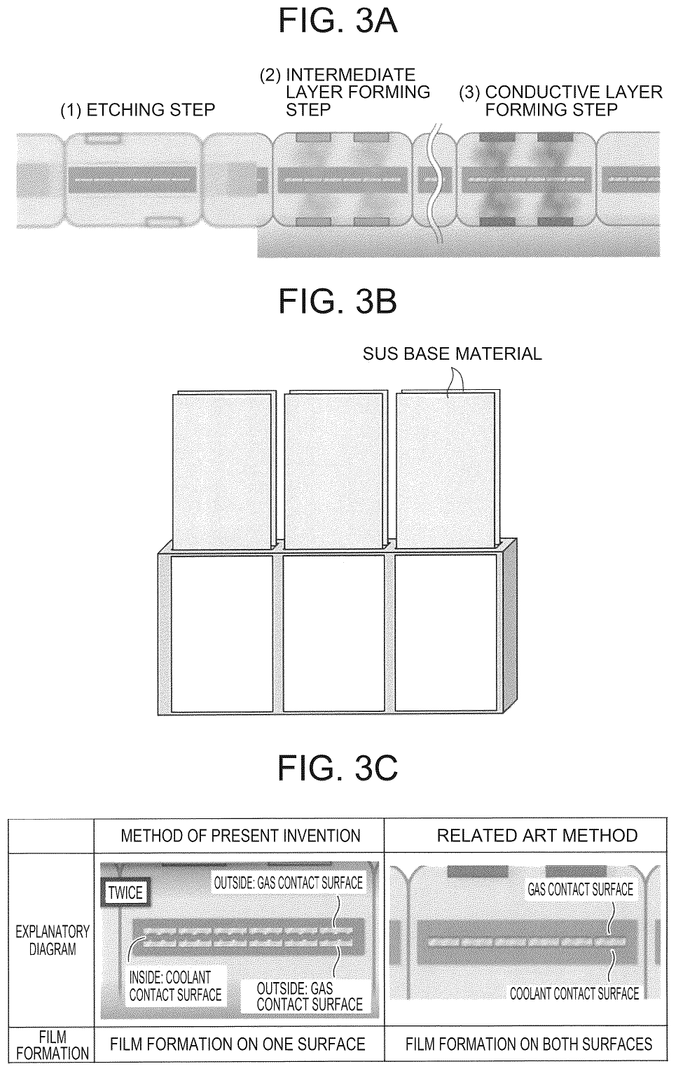

FIG. 3A to FIG. 3C show the embodiment of the method for manufacturing the fuel cell separator of the present disclosure in more detail. FIG. 3A is a diagram which specifically shows the surface treatment step in the manufacturing method of the related art. In the surface treatment step, (1) the passive film on the surface of the SUS base material is removed by an etching process, (2) a corrosion-resistant metal intermediate layer is formed by an intermediate layer forming step, and (3) a conductive layer is formed by a conductive layer forming step. FIG. 3B specifically shows the characteristic of the present disclosure, and is a diagram schematically showing how two SUS base materials each having a conductive passive film are stacked together such that the coolant contact surfaces thereof face each other and the gas contact surfaces thereof are exposed, and placed in a frame (jig). FIG. 3C is a diagram showing a comparison between the method of the present disclosure and the method of the related art. Therefore, according to the present disclosure, the surface treatment step of the related art in FIG. 3A is modified by a manufacturing method in which two or more SUS base materials are installed as shown in FIG. 3B. In other words, in the present disclosure, the manufacturing method is changed from that of the related art for forming films on both the coolant contact surface and the gas contact surface to the manufacturing method for forming a film only on the gas contact surface (one surface). Formation of a film only on one surface makes it possible to load twice as many separators on a rack (cart) during film formation, and as shown in FIG. 3C, the efficiency of the film formation process on the separators is enhanced twice.

The fuel cell separator manufactured according to the present disclosure is a component of a single cell in the fuel cell, and is disposed on both surfaces of a film electrode assembly (an electrolyte film, and anode and cathode electrode layers disposed on both the surfaces of the electrolyte film).

The fuel cell separator manufactured according to the present disclosure is adhesively bonded to components of a fuel cell known in the present technical field, such as a film electrode assembly and a seal member, with, for example, an adhesive agent, thereby manufacturing the fuel cell.

A fuel cell manufactured by using a fuel cell separator produced according to the present disclosure can be used in various electrochemical devices such as solid polymer fuel cells.

### EXAMPLES

Some examples of the present disclosure will be described below, but it is not intended that the present disclosure is limited to components shown in the examples.

### 1. Manufacturing of Separator

### Comparative Example 1

A stainless steel base material having a channel shape formed therein was produced as a separator of Comparative Example 1 by press-molding a stainless steel plate having a thickness of 0.1 mm. Note that the stainless steel material was SUS304-BA.

### Reference Example 1

A separator of Reference Example 1 was produced by a method described in Example 1 of JP 2022-45138 A. Specifically, it is as follows.

A stainless steel base material (SUS304, 0.1 mm in thickness) having a channel shape formed therein was prepared as the base material. A PVD film forming apparatus (FC1200, manufactured by Hauzer) was used to form a corrosion-resistant metal intermediate layer and a carbon layer on both surfaces of the stainless steel base material. Specifically, after the stainless steel base material was first placed in a reaction vessel of an apparatus, the reaction vessel was evacuated and heated by an internal heater. Next, a pure Ti cathode target used for sputtering was etched (cleaned) with plasma Ar gas. Furthermore, in order to remove passive state present on the surface of the stainless steel base material, the stainless steel base material was etched with plasma Ar gas. Next, a titanium layer was formed by unbalanced magnetron sputtering (UBMS) using the above-mentioned pure Ti cathode target. The film forming condition for the titanium layer was set as follows.
Target film thickness: 250 nm
Processing temperature: 150° C.
Vacuum level: 2E-03 mbar
Input gas: Ar
Gas flow rate: 250 sccm
Bias voltage: PLS
Voltage value: −75 V
Frequency: 40 kHz
Off time during frequency: 5 μS
Ti cathode output: 8 kW/A/V
UBM coil current: 2 A
Revolution speed: 3 rpm

Next, a carbon layer was formed by arc ion plating (AIP) using high-purity ta-C raw material. The film forming condition for the carbon layer was set as follows:
Target film thickness: 50 nm
Processing temperature: 180° C.
Vacuum level: 2E-03 mbar
Input gas: Ar
Gas flow rate: 250 sccm
Bias voltage: PLS
Voltage value: −20 V
Frequency: 40 kHz
Off time during frequency: 5 μS
C cathode output: 60 kW/A/V
Revolution speed: 4 rpm

During the etching and film formation, the stainless steel base material was rotated as appropriate to form a titanium layer and a carbon layer on both surfaces thereof. Through the above steps, the separator of Reference Example 1 was obtained.

### Example 1

A step of preparing a conductive base material by providing a conductive passive film on the base material of (i) will be described.

### (A) Step of Implanting Fluorine Into Passive Film

First, a stainless steel base material (SUS304, 0.1 mm in thickness) having a channel shape formed therein was prepared as the base material. The prepared base material was dipped in acetone and subjected to ultrasonic cleaning, and then heated in the atmosphere at 300° C. for 5 minutes. Thereafter, a HF aqueous solution of 5% by mass was used to perform a dip treatment at 30° C. for 1 minute, and then washing with distilled water and drying with cold air (25° C.) were performed.

### (B) Step of Imparting Lithium Into Passive Film

Next, a cathodic electrolysis treatment was performed in a 1 kmol/m³ LiOH aqueous solution at 1 A/dm² for 1 minute, and then washing with distilled water and drying with cold air (25° C.) were performed.

### (C) Step for Eluting Iron From Passive Film

Thereafter, a 5% by mass HF aqueous solution was used to perform a dip treatment at 30° C. for 10 seconds, and then washing with distilled water and drying with cold air (25° C.) were performed.

(ii) Step of stacking two conductive base materials will be described. The two conductive base materials each having conductive passive films formed on both surfaces thereof obtained in the step of (i) were stacked together such that the gas contact surfaces of the conductive base materials which would come into contact with gas were exposed and the coolant contact surfaces of the conductive base material which would come into contact with coolant were faced each other inward, and placed in a frame (jig).

(iii) A step of performing the PVD treatment on the exposed gas contact surfaces of the two conductive base materials to form a corrosion-resistant metal intermediate layer and a conductive layer (carbon layer) will be described. The PVD treatment was performed on the exposed gas contact surfaces of the two conductive base materials stacked together in the step of (ii) to form a corrosion-resistant metal intermediate layer on the base material and a carbon layer on the corrosion-resistant metal intermediate layer. The condition of the PVD treatment for forming the corrosion-resistant metal intermediate layer and the carbon layer on the gas contact surfaces of the conductive base materials was the same as that in Reference Example 1.

### 11. Evaluation of Separator

### Measurement of Contact Resistance

The contact resistance was measured between GDL (manufactured by Toray Industries, Inc.) and each of Comparative Example 1 (a separator with no PVD treatment and only press), Reference Example 1 (a separator having a titanium layer and a carbon layer on both the coolant contact surface and the gas contact surface), and Example 1 (a separator having a conductive passive film on the coolant contact surface and having a titanium layer and a carbon layer on the gas contact surface). The load pressure was set to 1.0 MPa. Thereafter, each of the separators was dipped in an FCC solution (ethylene glycol:water=50:50), and left at 85° C. for 1000 hours (endurance test). Next, the contact resistance was measured between the GDL (manufactured by Toray Industries, Inc.) and each of the samples after the endurance test in the same manner as described above.

### TOF-SIMS Depth Analysis

TOF-SIMS depth analysis was performed on the coolant contact surface of the separator of Example 1.

### XPS Analysis

XPS analysis was performed on the coolant contact surface of the separator of Example 1. The measurement condition for the XPS analysis was as described above.

### GD-OES Depth Analysis

GD-OES depth analysis was performed on the coolant contact surfaces of the separators of Example 1 and Comparative Example 1. The measurement conditions for the GD-OES depth analysis were as described above.

### TEM-EDX Element Mapping Analysis

TEM-EDX element mapping analysis was performed on the coolant contact surface of the separator of Example 1.

### III. Evaluation Result of Separators

### Contact Resistance Measurement Results

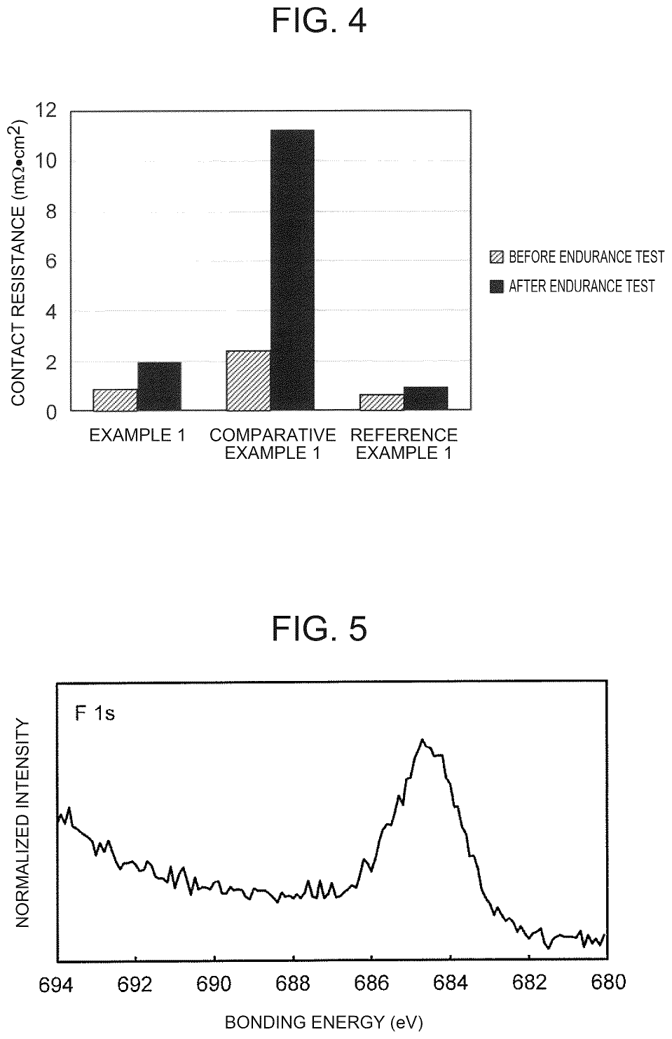

FIG. 4 shows the contact resistance results for Comparative Example 1, Reference Example 1, and Example 1. From FIG. 4, it was found that before and after the endurance test, Example 1 showed a very low contact resistance of 5 mΩ·cm² or less, especially 3 mΩ·cm² or less which was equivalent to that of Reference Example 1.

Results of XPS Analysis, GD-OES, TOF-SIMS Depth Analysis, and TEM-EDX Element Mapping Analysis

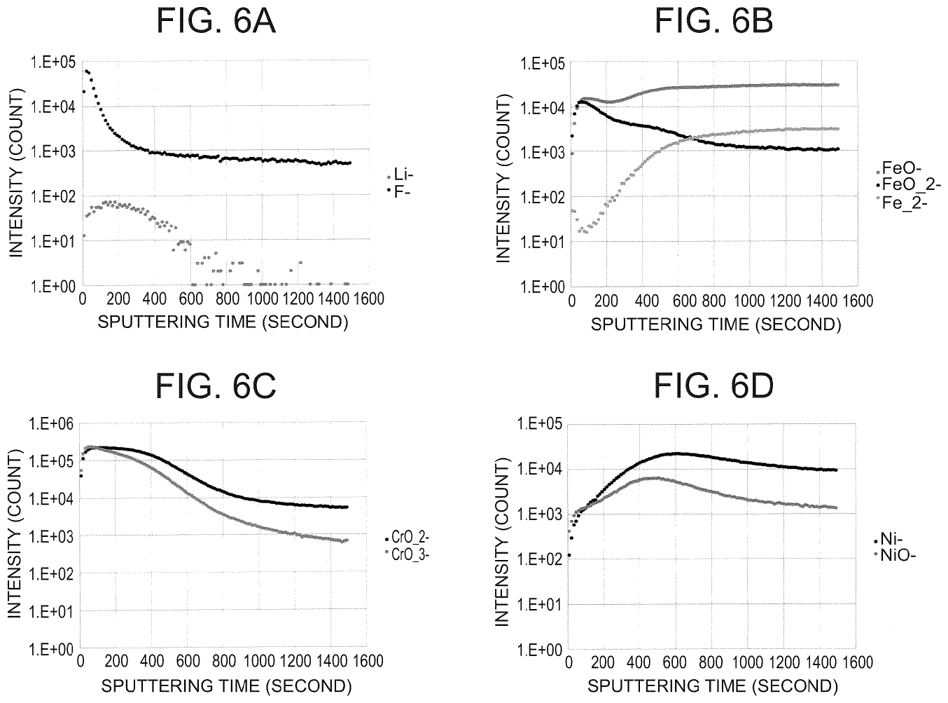

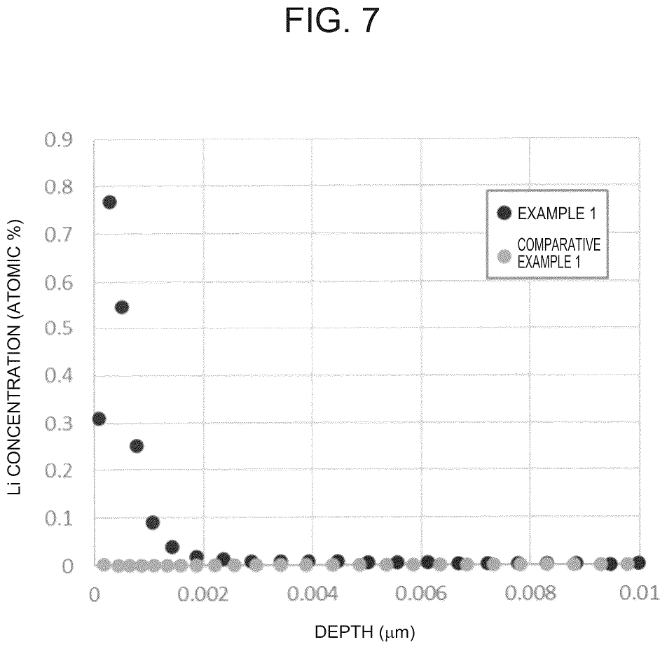

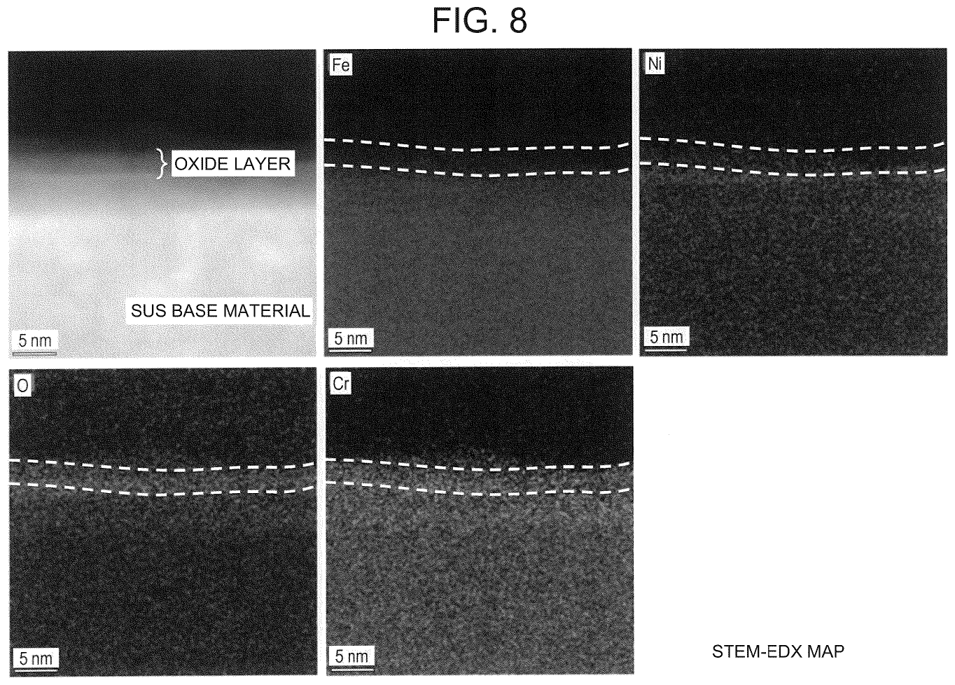

FIG. 5 shows a result of XPS analysis for the coolant contact surface of Example 1, FIG. 6A to FIG. 6D show a result of TOF-SIMS depth analysis for the coolant contact surface of Example 1, FIG. 7 shows a result of GD-OES depth analysis for the coolant contact surface of Example 1, and FIG. 8 shows a result of TEM-EDX element mapping analysis for the coolant contact surface of Example 1. From FIG. 5, it was found that a peak caused by the bonding energy of fluoride existed between 682 eV and 688 eV for the coolant contact surface of Example 1. From FIG. 6A to FIG. 6D, it was found for the coolant contact surface of Example 1 that Li, F, and Cr were detected for a short sputtering time, that is, in the neighborhood of the surface of the coolant contact surface. From FIG. 7, Li was detected in a shallow range of depth 0 to 0.002 μm for the coolant contact surface of Example 1. Furthermore, no Li was detected for the coolant contact surface of Comparative Example 1. From FIG. 8, it was found that the oxide layer has a high Cr ratio for the coolant contact surface of Example 1. Therefore, From FIG. 5 to FIG. 8, it was found for the separator of Example 1 that a conductive passive film containing F, Li, and Cr contributing to the electrical conductivity of the coolant contact surface was formed on the coolant contact surface.

From the above, it was found that even when relevant corrosion-resistant metal intermediate layer and conductive layer were not formed, a conductive passive film which was more desirable in productivity than the relevant corrosion-resistant metal intermediate layer and conductive layer was formed on the coolant contact surface of the separator, whereby a sufficiently low contact resistance could be maintained for the resulting separator even after endurance testing.

What is claimed is:

1. A separator formed of stainless steel for a fuel cell, comprising:
a coolant contact surface that is configured to come into contact with a coolant; and
a gas contact surface that is configured to come into contact with gas, wherein
the coolant contact surface has a conductive passive film, and
the gas contact surface has a corrosion-resistant metal intermediate layer on a base material and a conductive layer on the corrosion-resistant metal intermediate layer.

2. The separator according to claim 1, wherein:
a Cr/Fe ratio related to atomic % in the conductive passive film analyzed by surface X-ray photoelectron spectroscopy is equal to 2 or more;
a concentration of F in the conductive passive film analyzed by surface X-ray photoelectron spectroscopy is equal to 0.1 atomic % or more; and
a concentration of Li in the conductive passive film analyzed by glow discharge optical emission spectroscopy is equal to 0.05 atomic % or more.

3. A method for manufacturing a separator for a fuel cell, comprising:
(i) applying a conductive passive film to a base material of stainless steel to prepare a conductive base material;
(ii) stacking two or more conductive base materials obtained in the applying such that a gas contact surface of each of the two or more conductive base materials is entirely exposed, the gas contact surface being to come into contact with gas entirely; and
(iii) performing a physical vapor deposition treatment on the gas contact surfaces of the two or more conductive base materials stacked in the stacking to form corrosion-resistant metal intermediate layers on the base materials and conductive layers on the corrosion-resistant metal intermediate layers, the gas contact surfaces of the two or more conductive base materials being exposed.

4. The method according to claim 3, wherein the applying includes (A) implanting fluorine into a passive film, (B) implanting lithium into the passive film, and (C) eluting iron in the passive film.
